(19) United States
(12) Patent Application Publication
(10) Pub. No.: US 2004/0174096 A1
(43) Pub. Date: Sep. 9, 2004

(54) Piezo actuator for operating a mechanical component

(76) Inventors: Udo Lux, Baunach (DE); Henning Teiwes, Hallstadt (DE)

Correspondence Address: RONALD E. GREIGG, GREIGG & GREIGG P.L.L.C., 1423 POWHATAN STREET, UNIT ONE, ALEXANDRIA, VA, 22314, US

(21) Appl. No.: 10/432,674

(22) PCT Filed: Jul. 13, 2002
(86) PCT No.: PCT/DE02/02578

(30) Foreign Application Priority Data
Sep. 27, 2001 (DE) 101 47 669.8

(51) Int. Cl. H01L 41/04; H02N 2/04

(52) U.S. Cl. 310/348

(57) ABSTRACT

The present invention relates to a piezoelectric actuator with a piezoelectric element, which is prestressed by means of a cup-shaped spring element having a simple design that is economical to produce and is capable of furnishing the requisite strong static and dynamic forces for prestressing the piezoelectric element, with a very small installation space.

### PRIOR ART

The present invention relates to a piezoelectric actuator having a piezoelectric element for actuating a mechanical component, in particular for an injection injector for fuel metering in an internal combustion engine, in which the piezoelectric element is prestressed by means of a spring element.

Piezoelectric actuators are used, for instance in fuel injection valves, for actuating a control valve which in turn actuates a nozzle needle of the fuel injection valve. Such piezoelectric actuators are cylindrical or block-shaped elements, constructed by stacking ceramic disks, that convert electrical energy directly into a motion, or more precisely a stroke. In modern fuel injection valves for internal combustion engines, high switching frequencies and very switching times must be achieved with the piezoelectric actuators. To prevent the mass forces that occur from causing self-destruction of the actuator, a high preliminary load must be applied to the piezoelectric actuator. In fuel injection valves, for instance, a preliminary load of approximately 500 N to 1000 N must be applied.

In order to bring such high prestressing forces to bear on the piezoelectric element, it has been proposed, for instance by German Patent Disclosure DE 199 28 179 A1, that the piezoelectric element be fastened between a cup spring and a spiral spring. From German Patent Disclosure DE 199 28 186 A1, it is also known for the piezoelectric element to be connected to a thrust bolt, so that the piezoelectric element is mechanically connected to a wave washer that is prestressed for tension. The wave washer is anchored in a region of the housing. From German Patent Disclosure DE 199 28 183 A1, a piezoelectric element is moreover known which is fastened by a spring element between two platelike components. However, a disadvantage of the known prestressing devices for the piezoelectric element is that they are relatively complicated to install and have a large number of individual parts. This makes it relatively expensive to produce such piezoelectric actuators.

### ADVANTAGES OF THE INVENTION

The piezoelectric actuator of the invention as defined by the characteristics of claim 1 has the advantage over the prior art of being very compact in design and very economical to produce. To that end, for prestressing the piezoelectric element, the spring element is embodied as cup-shaped, so that it can be stamped out of a metal sheet in the form of a round, for instance, and then put into its cup-shaped form by deep-drawing, for instance. It should be noted that according to the invention, the term “cup-shaped form” is understood to mean not only a circular outer circumference but also, for instance, an oval, rectangular, square or polygonal outer circumference. Thus the cup-shaped spring element has a bottom region and a wall region, the latter being disposed essentially perpendicular to the bottom region on the outer circumference, or more precisely on the outer edge of the bottom region. Because of the use of the cup-shaped spring element according to the invention, the piezoelectric actuator of the invention has little installation space. Particularly in comparison with cup springs, less hysteresis is obtained with the use of the cup-shaped spring element. Moreover, force transmission free of shear force can be accomplished. Since the cup-shaped spring element can be produced simply and with high replicability, there are great cost advantages in production.

To furnish a simple construction of the piezoelectric actuator, the piezoelectric element is preferably disposed in a cup-shaped housing.

In a preferred embodiment of the present invention, the cup-shaped spring element has one or more recesses. Preferably, the recesses are selected such that a desired spring characteristic can be furnished by the cup-shaped spring element.

Especially preferably, the recesses of the cup-shaped spring element are embodied as slitlike.

To furnish spring properties in both the radial and axial directions of the cup element, the recesses of the cup-shaped spring element are preferably embodied such that they have a smooth transition from the bottom region into the wall region of the spring element.

The cup-shaped spring element is preferably in contact with the housing of the piezoelectric element via a point-type contact. To achieve uniform introduction of force into the cup-shaped spring element, this contact is preferably located at the center point or on a center axis of the cup-shaped spring element.

The housing of the piezoelectric element and the hemispherical connecting element can for instance be made in one piece.

To enable compensation for temperature-caused changes in length of the piezoelectric element, the cup-shaped spring element is preferably in contact with a piston of a hydraulic coupler. By volumetric adaptation of a fluid chamber in the hydraulic coupler, the temperature-caused change in length of the piezoelectric element can be compensated for. The hydraulic coupler can furthermore be embodied such that it steps up the relatively short stroke of the piezoelectric element.

To enable simple fastening of the cup-shaped spring element to the piston of the hydraulic coupler, the piston preferably has an attachment that corresponds to the inner circumference of the cup-shaped spring element. The cup-shaped spring element is preferably connected to the attachment of the piston by means of a press fit.

The piezoelectric actuator of the invention is used particularly in a fuel injection valve for common rail injection systems; preferably, a control valve is actuated by the piezoelectric actuator and in turn actuates a valve member of the fuel injection valve.

### DRAWING

Two exemplary embodiments of the invention are shown in the drawing and will be explained in further detail in the ensuing description.

FIG. 1 shows a schematic sectional view of a piezoelectric actuator with a cup-shaped spring element in accordance with a first exemplary embodiment of the present invention;

FIG. 2 shows a sheet-metal round, from which the cup-shaped spring element shown in FIG. 1 is made;

FIG. 3 shows a sheet-metal round for producing a cup-shaped spring element in accordance with a second exemplary embodiment;

FIG. 4 shows a plan view on the cup-shaped spring element in the second exemplary embodiment; and

FIG. 5 shows a side view of the cup-shaped spring element in the second exemplary embodiment.

### DESCRIPTION OF THE EXEMPLARY EMBODIMENTS

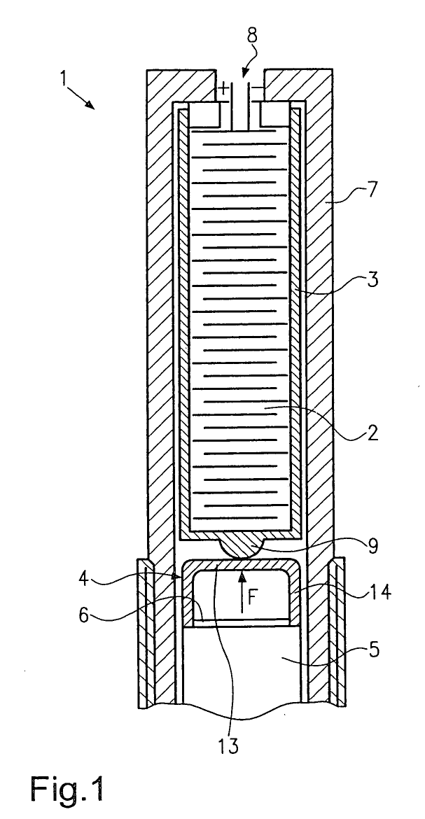

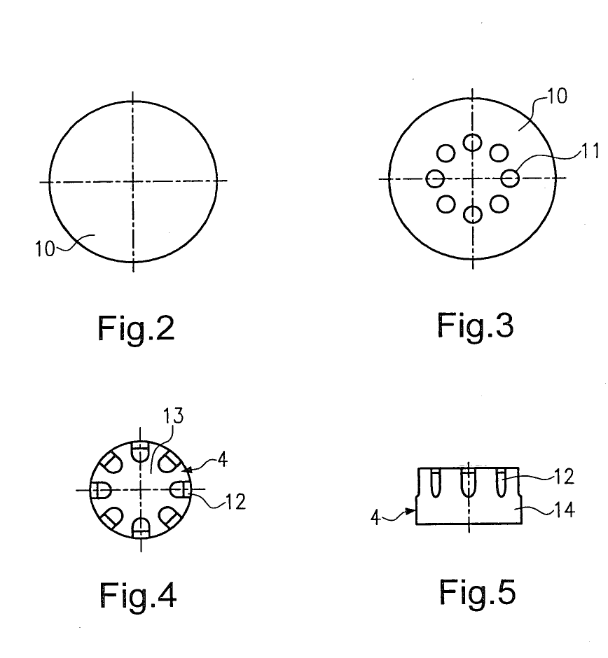

Referring to FIGS. 1 and 2, a piezoelectric actuator with a cup-shaped spring element in accordance with a first exemplary embodiment will now be described.

The piezoelectric actuator shown in FIG. 1 is used in a valve 1 for injecting fuel. For reasons of simplicity in the drawing, only the components of the valve 1 essential to the invention are shown. As shown in FIG. 1, a piezoelectric element 2, stacked from a plurality of ceramic disks, is disposed in a cup-shaped housing 3. An electrical terminal 8 for the piezoelectric element 2 is provided on the open end of the cup-shaped housing 3. The piezoelectric element 2 is in contact via the housing 3 with a cup-shaped spring element 4. More precisely, a hemispherical connecting element 9 is embodied on the housing 3, in order to establish a pointlike connection between the housing 3 and the cup-shaped spring element 4. The cup-shaped spring element 4 is embodied essentially cylindrically and has both a bottom region 13 and lateral, cylindrical-annular wall regions 14.

As shown in FIG. 1, the cup-shaped spring element 4 is connected directly to a piston 5 of a hydraulic coupler. To that end, on the piston 5, there is an annular shoulder 6, with which the cup-shaped spring element 4 is connected by means of a press fit. The cup-shaped spring element 4 is disposed in such a way in the valve 1 that is can exert prestressing on the piezoelectric element 2 in the direction of the arrow F via the housing 3. The piezoelectric actuator 2, spring element 4 and hydraulic coupler are disposed in a housing 7 of the valve 1. The piezoelectric element 2 is braced on the housing 7 via an intermediate component.

In FIG. 2, a round 10 of sheet metal is shown, from which the cup-shaped spring element 4 can be made, for instance by means of deep drawing. As a result, the cup-shaped spring element 4 can be produced especially simply and economically. After the deep drawing, still other production steps can be performed, such as trimming and hardening.

By means of the cup-shaped spring element 4 according to the invention, force transmission free of shear force can be accomplished from the piezoelectric element 2 to the piston 5 of the hydraulic coupler. The cup-shaped spring element 4 of the invention also has a smaller installation space, in comparison to the use of conventional compression springs, so that in particular the axial length of the valve 1 can be reduced. According to the invention, only one spring element on one side of the piezoelectric element 2 is required for the prestressing. The cup-shaped spring element 4 according to the invention can assure that the requisite high static and dynamic values can be brought to bear.

In FIGS. 3-5, a spring element in accordance with a second exemplary embodiment is shown. Identical elements are identified by the same reference numerals as in the first exemplary embodiment.

As can be seen particularly from FIGS. 4 and 5, the cup-shaped spring element 4 of the second exemplary embodiment, compared to the first exemplary embodiment, has a plurality of slitlike recesses 12. The recesses 12 are disposed on the cup-shaped spring element 4 in such a way that they extend both partway into the lateral wall regions 14 and into the bottom region 13 of the spring element 4 (compare FIGS. 4 and 5). Because of the embodiment of these recesses in the transitional region from the bottom region 13 to the lateral edge region 14, different spring characteristics are obtained than with the spring element of the first exemplary embodiment. The number, size and position of recesses on the cup-shaped spring element 4 can be varied as needed in order to be obtain different spring characteristics.

In FIG. 3, a round 10 is shown from which the cup-shaped spring element 4 of the second exemplary embodiment can be produced by deep drawing. A plurality of recesses 11 are formed in the round 10, located on a circular circumference around the center point of the circular round. A cylindrical deep-drawing tool engages the round 10 shown in FIG. 3 in such a way that its outer circumference rests in the region of the recesses 11. In this way, the recesses 12 shown in FIGS. 4 and 5 are obtained. The round 10 shown in FIG. 3 can for instance be produced by being stamped out of a flat sheet-metal material.

The present invention thus relates to a piezoelectric actuator with a piezoelectric element 2 that is prestressed by means of a spring element 4 embodied in cup-shaped form. The cup-shaped spring element 4 has a simple construction that can be produced economically, and it can furnish the requisite high static and dynamic forces for prestressing the piezoelectric element 2 with only very little installation space.

The above description of the exemplary embodiments of the present invention is intended solely for illustrative purposes and not for the sake of limiting the invention. Within the scope of the invention, various changes and modifications may be made without departing from the scope of the invention or its equivalents.

1. A piezoelectric actuator having a piezoelectric element (2) for actuating a mechanical component (5), in particular for an injection injector for fuel metering in an internal combustion engine, in which the piezoelectric element (2) is prestressed by means of a spring element (4), characterized in that the spring element (4) is embodied cup-shaped.

2. The piezoelectric actuator of claim 1, characterized in that the piezoelectric element (2) is disposed in a cup-shaped housing (3).

3. The piezoelectric actuator of claim 1 or 2, characterized in that the cup-shaped spring element (4) has at least one recess (12).

4. The piezoelectric actuator of one of claims 1-3, characterized in that the recesses (12) are embodied in slitlike form.

5. The piezoelectric actuator of claim 3 or 4, characterized in that the recesses (12) of the cup-shaped spring element (4) make a smooth transition from a bottom region (13) to a wall region (14).

6. The piezoelectric actuator of one of claims 2-5, characterized in that the cup-shaped spring element (4) is in contact with the cup-shaped housing (3) of the piezoelectric element (2) via a point-type contact.

7. The piezoelectric actuator of claim 6, characterized in that the point-type contact is furnished by a hemispherical connecting element (9) provided on the outer bottom of the cup-shaped housing (3).

8. The piezoelectric actuator of one of claims 1-7, characterized in that the cup-shaped spring element (4) is in contact with a piston (5) of a hydraulic coupler.

9. The piezoelectric actuator of claim 8, characterized in that an encompassing shoulder (6) for receiving the spring element (4) is embodied on the piston (5), on the side oriented toward the spring element (4).

10. The piezoelectric actuator of one of claims 1-9, characterized in that the cup-shaped spring element (4) has a circular, oval, rectangular, square, or polygonal outer circumference.
